(19) United States
(12) Patent Application Publication
(10) Pub. No.: US 2026/0271196 A1
(43) Pub. Date: Sep. 10, 2026

(54) MONOLITHIC ENCLOSURE FOR A PRINTED CIRCUIT BOARD

(71) Applicant: SK Hynix NAND Product Solutions Corp. (dba Solidigm), Rancho Cordova, CA (US)

(72) Inventor: Hardeep Singh, Folsom, CA (US)

(21) Appl. No.: 19/071,339

(22) Filed: Mar. 5, 2025

(51) Int. Cl. H05K 5/00; H05K 7/14; H05K 7/20

(52) U.S. Cl. CPC H05K 5/0069; H05K 7/1427; H05K 7/20409

(57) ABSTRACT

A device includes a printed circuit board (PCB) and a rectangular prism-shaped enclosure housing the PCB. The enclosure includes an opening on a lateral side to allow the PCB to slide into the enclosure, a top side of the enclosure, at least one boss extending from the top side of the enclosure in a direction of a bottom side of the enclosure, and at least one gasket arranged between the at least one boss and the PCB. The at least one boss electrically couples the PCB to the enclosure, and the at least one gasket is in contact with both the at least one boss and with the PCB.

### TECHNICAL FIELD

The present disclosure is directed to devices and methods for housing a printed circuit board (PCB) in a monolithic rectangular-prism shaped enclosure.

### SUMMARY

In accordance with the present disclosure, devices and methods are disclosed herein for housing a PCB. The housing may include an enclosure that provides efficient heat transfer between the PCB (e.g., on which solid state devices (SSDs) or any other suitable electronic devices may be mounted) and the enclosure (e.g., including cooling elements coupled to the exterior of the enclosure). Compared to other enclosures, a monolithic rectangular-prism shaped enclosure for housing a PCB reduces thermal asymmetry (e.g., which can result in different temperatures on the top and bottom covers of an enclosure), and removes gaps (e.g., gaps between top and bottom covers of an enclosure) in the enclosure that need to be filled with materials (e.g., thermal gaskets including oil) that may spill over.

In accordance with some embodiments of the present disclosure, a device includes a PCB, and a rectangular prism-shaped enclosure housing the PCB. The enclosure includes an opening on a lateral side to allow the PCB to slide into the enclosure, a top side of the enclosure, at least one boss extending from the top side of the enclosure in a direction of a bottom side of the enclosure, and at least one gasket arranged between the at least one boss and the PCB. The at least one boss electrically couples the PCB to the enclosure, and the at least one gasket is in contact with both the at least one boss and with the PCB.

In some embodiments, the top side and the PCB are thermally coupled using a thermal interface material (TIM) layer.

In some embodiments, the TIM layer includes a slidable surface coupled to the top side and a sticky surface coupled to the PCB.

In some embodiments, the device further includes a first circuitry disposed on a first side of the PCB.

In some embodiments, the device further includes a second circuitry disposed on a second side of the PCB opposite the first side.

In some embodiments, each of the at least one gasket is electrically conductive.

In some embodiments, each of the at least one gasket includes a slidable surface coupled to the at least one boss and a sticky surface coupled to the PCB.

In some embodiments, the slidable surface includes a low friction material.

In some embodiments, the sticky surface includes a conductive adhesive.

In some embodiments, the device further includes at least one cooling fin extending from an outer surface of the enclosure.

In some embodiments, the device further includes a cooling plate in contact with at least one outer surface of the enclosure.

In accordance with some embodiments of the present disclosure, a method of manufacturing a device is provided. The device includes a PCB and a rectangular prism-shaped enclosure the enclosure including an opening on a lateral side to allow the PCB to slide into the enclosure, a top side of the enclosure, and at least one boss extending from the top side of the enclosure in a direction of a bottom side of the enclosure. The method includes sliding the PCB through the opening, and arranging at least one gasket between the at least one boss and the PCB. The at least one boss electrically couples the PCB to the enclosure, and the at least one gasket is in contact with the respective ones of the at least one boss and with the PCB.

In some embodiments, the method further includes thermally coupling the top side and the PCB using a thermal interface material (TIM) layer.

In some embodiments, the TIM layer includes a slidable surface coupled to the enclosure and a sticky surface coupled to the PCB.

In some embodiments, the PCB includes a first circuitry disposed on a first side of the PCB.

In some embodiments, the PCB further includes a second circuitry disposed on a second side of the PCB opposite the first side.

In some embodiments, each of the at least one gasket is electrically conductive.

In some embodiments, each of the at least one gasket includes a slidable surface coupled to the at least one boss and a sticky surface coupled to the PCB.

In some embodiments, the slidable surface includes a low friction material.

In accordance with some embodiments of the present disclosure, a rectangular prism-shaped enclosure to house a PCB includes an opening on a lateral side to allow the PCB to slide into the enclosure, a top side of the enclosure, at least one boss extending from the top side of the enclosure in a direction of a bottom side of the enclosure, and at least one gasket arranged between the at least one boss and the PCB. The at least one boss electrically couples the PCB to the enclosure, and the at least one gasket is in contact with both the at least one boss and with the PCB.

### BRIEF DESCRIPTION OF THE DRAWINGS

The following description includes discussion of figures having illustrations given by way of example of implementations of embodiments of the disclosure. The drawings should be understood by way of example, and not by way of limitation. As used herein, references to one or more “embodiments” are to be understood as describing a particular feature, structure, and/or characteristic included in at least one implementation. Thus, phrases such as “in some embodiments” appearing herein describe various embodiments and implementations, and do not necessarily all refer to the same one or more embodiment. However, they are also not necessarily mutually exclusive. In the drawings:

FIG. 1 shows a cross-sectional view diagram of a rectangular-prism shaped enclosure housing a PCB, in accordance with some embodiments of the present disclosure;

FIG. 2 shows a cross-sectional view diagram of a rectangular-prism shaped enclosure housing a PCB, where the enclosure includes additional cooling elements, in accordance with some embodiments of the present disclosure; and

FIG. 3 shows an illustrative flowchart of a method to house a PCB in a rectangular-prism shaped enclosure, accordance with some embodiments of the present disclosure.

### DETAILED DESCRIPTION

Enclosures to house PCBs (e.g., on which SSDs or any other suitable electronic devices may be mounted) are typically manufactured as two halves (e.g., top and bottom enclosure components) that get assembled together. The two halves are typically connected with each other using mechanical fasteners (e.g., screws, bolts, rivets, any other suitable fasteners), and sealed with compressible electrical gaskets (e.g., offering electrostatic discharge (ESD), electromagnetic interface (EMI), other related electrical benefits, or any combination thereof) for electrical grounding, and/or sealed with thermal gaskets to enhance thermal performance. Further, the enclosure halves are typically electrically connected (e.g., via bosses) to the PCB for electronically grounding the PCB. Heat generated by the components of the PCB gets transferred to top and bottom side enclosures through TIMs and dissipated by air-driven convection, cooling fins, contact with a mobile cooling fluid (e.g., water or any other coolant fluid, or any combination thereof). Due to gaps (e.g., the gap between the top half and the bottom half) in the enclosure, the temperatures of the different parts (e.g., the top half and the bottom half) of the enclosure may be asymmetric. Further, the thermal and/or electrical gaskets used to connect the two enclosure halves may leak (e.g., the oil on the gaskets may leak), may create imperfect seals (e.g., that affect thermal insulation and electrical isolation), may increase complexity in assembling processes, and may increase the cost of materials.

Compared to other approaches, the devices and methods disclosed herein are provided for efficient heat transfer between a PCB (e.g., on which SSDs or any other electronic devices may be mounted) and all sides of a monolithic enclosure housing the PCB. Furthermore, a monolithic enclosure without interfacing parts (e.g., thermal gaskets, ESD gaskets, EMI gaskets, or any other suitable interfacing parts), as provided herein, may reduce leakage (e.g., oil leakage from the gaskets), assembly complexity, and cost of materials.

In some embodiments, the PCB provided within the monolithic enclosure may have any form factor (e.g., size, shape, physical specifications, etc.), and may include circuitry arranged on a top side or bottom side of the PCB. The circuitry may include first and second circuitries, respectively arranged on the top and bottom PCB sides. The circuitry may include electrical components, at least one of which is a heat-generating electrical component. The electrical components of the circuitry may be any suitable high-performance electrical component (e.g., an integrated circuit device, such as an application-specific integrated circuit (ASIC) device). The device may further include TIMs arranged between the circuitry on the PCB and a proximal inner surface of the enclosure. The TIMs may be thermally conductive to transfer heat from the circuitry to the enclosure. The TIMs may also provide mechanical support for immobilizing the PCB within the monolithic enclosure.

In some embodiments, the thermal connections (e.g., thermally conductive TIMs between the circuitry on the PCB and the enclosure) and/or electrical connections (e.g., electrically conductive bosses and the ESD/EMI gaskets) are arranged within the enclosure to thermally and/or electrically couple the PCB to the enclosure. For example, thermally coupling the PCB to the enclosure can further promote efficient heat transfer from the circuitry on the PCB to the enclosure. Electrically coupling the PCB to the enclosure can provide a common ground between the PCB (including circuitry mounted to the PCB) and any other electronics or power sources with which the enclosure can share a ground connection.

In contrast to using an openable enclosure, the components inside the monolithic rectangular-prim shaped enclosure (e.g., including at least the PCB, thermal, and electrical connections) cannot be layered upon each other (e.g., in a bottom-up approach) within the enclosure during assembly. For example, the opening of the enclosure may be along a narrow thickness dimension, such that sliding the PCB into the opening may be the only method to insert the PCB inside the enclosure. In some embodiments, the PCB may be slid (e.g., as facilitated by slidable gaskets and/or slidable TIMs) into and electrically coupled with the monolithic enclosure using electrically conductive gaskets which stick (e.g., using a conductive adhesive, or any other suitable sticky material) to the PCB on one side, and are slidable (e.g., using graphite, metal, mylar, polyamide, or any other low friction material) on the other side.

In some embodiments, an outer surface of the enclosure may include cooling fins that increase the surface area of the enclosure and cause more efficient heat dissipation. An outer surface of the enclosure may further be contacted with a cold plate to dissipate heat. Either or both of these cooling approaches help dissipate the heat that is generated from the circuitry while it is in operation. As used herein, the heat generated by the circuitry may include the thermal output of electrical components of the circuitry (e.g., high-performance integrated circuit chips or cores) disposed on the PCB.

For purposes of brevity and clarity, the features of the disclosure described herein are in the context of a PCB that is housed by a monolithic enclosure and is coupled to the enclosure using conductive bosses and gaskets. However, the principles of the present disclosure may be applied to any other suitable context in which an enclosure houses a PCB.

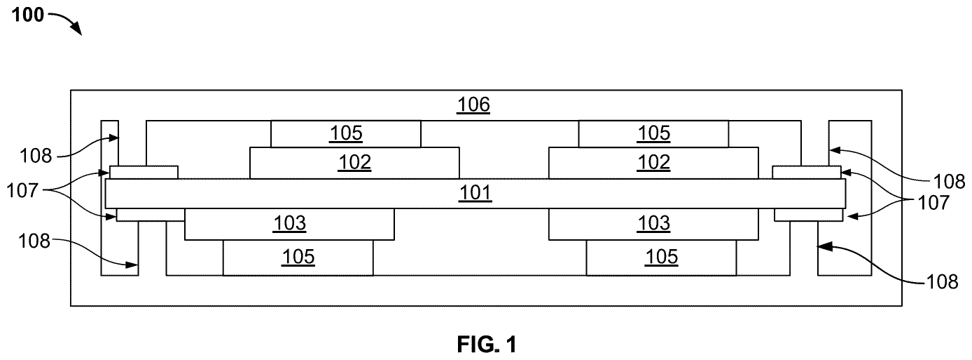

The subject matter of this disclosure may be better understood by reference to FIGS. 1-3.

FIG. 1 shows a cross-sectional view diagram of a monolithic rectangular-prism shaped enclosure housing a PCB, in accordance with some embodiments of the present disclosure. Device 100 includes PCB 101 with multiple iterations of top circuitry 102, multiple iterations of bottom circuitry 103, enclosure 106, and respective TIM layers 105 connecting the multiple iterations of top circuitry 102 and the multiple iterations of bottom circuitry 103 to the enclosure 106. The enclosure 106 includes electrically conductive bosses 108 contacting or protruding from one or more inner surface(s) of the enclosure 106. The PCB 101 is electrically coupled to the enclosure 106 by the bosses 108. Electrically (e.g., ESD/EMI) conductive gaskets 107 are arranged be in contact with the bosses 108 to electrically couple PCB 105 to the enclosure 108.

In some embodiments, any instance of top circuitry 102 and/or the bottom circuitry 103 includes at least one electrical component (e.g., an ASIC) which may generate heat while in operation. Heat may be transferred from the top and/or bottom circuitries 102 and 103, respectively, to the enclosure 106 via the TIMs 105. Using a monolithic enclosure 106 improves thermal load balancing and temperature symmetry between all sides of the enclosure 106, even when there is asymmetric heat generation by the top circuitry 102 and the bottom circuitry 103. Although not shown in FIG. 1, device 100 may include further thermal connections or layers that promote heat transfer from circuitry (e.g., top circuitry 102 and bottom circuitry 103) on a respective side of PCB 101 to the enclosure 106.

In some embodiments, each of the gaskets 107 has a respective slidable surface. The slidable surfaces of the gaskets 107 may include a slidable material (e.g., graphite, metal, mylar, polyamide, any other suitable low friction material) that permits PCB 101 from being slid into enclosure 106 (e.g., into the plane of the cross-section, as shown). The gaskets 107 may also have one or more sticky surfaces that provide adhesion to PCB 101 (or any other suitable surface). The sticky surfaces of the gaskets 107 may include a sticky material (e.g., a conductive adhesive). The slidable surfaces of the gaskets be thermally and/electrically coupled (e.g., by contacting) to the bosses 108. The sticky surfaces of the gaskets 107 be thermally and/electrically coupled (e.g., by contacting) to the PCB 101.

In some embodiments, the TIMs 105 also have one or more slidable surfaces. The slidable surfaces of the TIMs 105 may include a slidable material (e.g., graphite, metal, mylar, polyamide, any other suitable low friction material) that permits PCB 101 from being slid into enclosure 106. The TIMs 105 may also have one or more sticky surfaces that provide adhesion to the top circuitry 102 and/or the bottom circuitry 103. The sticky surfaces of the TIMs 105 may include a sticky material (e.g., a conductive adhesive). The slidable surfaces of the TIMs 105 may be thermally coupled (e.g., by contacting) to inner surfaces of the enclosure 106. The sticky surfaces of the TIMs 105 may be thermally coupled (e.g., by contacting) to the top circuitry 102 and/or the bottom circuitry 103.

In some embodiments, the enclosure 106 includes an opening on a lateral side (e.g., corresponding to a smallest dimension) of the enclosure 106. The PCB 101 may be slid into the opening along with the gaskets 107 which are stuck to the PCB 101 using the sticky side of the gaskets 107. The gaskets 107 may be arranged to align to one or more of the bosses 108 inside the enclosure 106. The slidable surfaces of the gasket 107 may come in contact with the bosses 108 and couple the PCB 101 to the enclosure 106 via the bosses 108.

For purposes of clarity and brevity, and not by way of limitation, the present disclosure is provided in the context of a device 100, which provides the features and functionalities disclosed herein. Device 100 may include, or may be at least partially implemented with, for example, a server device or storage device.

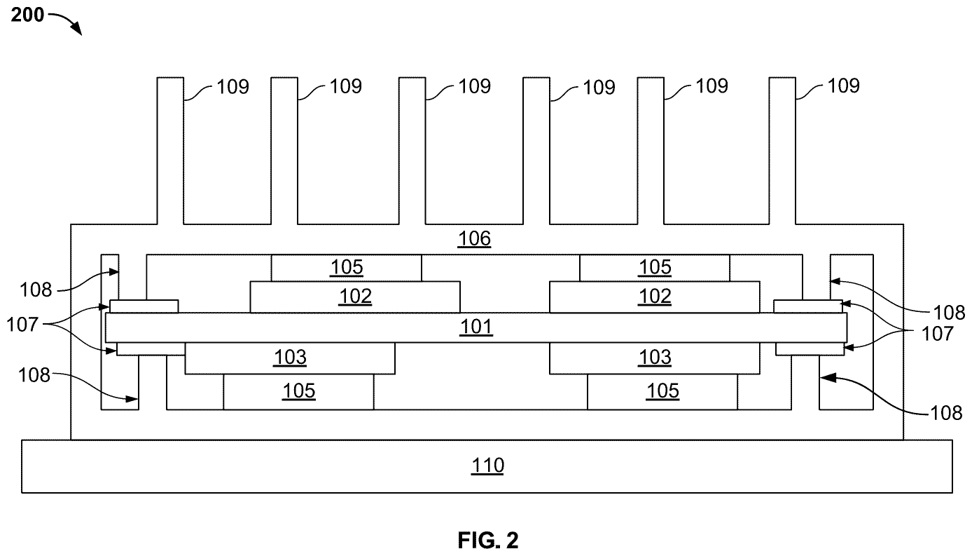

FIG. 2 shows a cross-sectional view of device 200, similar to device 100 in FIG. 1, but including additional cooling elements.

In some embodiments, the outer surface of the enclosure 106 includes cooling fins 109 to cool the PCB 101 housed in the enclosure 106. While multiple cooling fins 109 have been shown in device 200, there may be any suitable number of cooling fins 109. The use of cooling fins 109 increases the surface area of the enclosure, thereby increasing the efficiency at which heat from the enclosure 106 (i.e., the heat from the PCB 101) is dissipated. The cooling fins 109 may be protrusions from the enclosure 106, or be separately manufactured and attached to the enclosure 106. The materials used to make cooling fins 109 may include materials such as aluminum, copper, steel, copper alloys, or any other suitable conductor of heat.

In some embodiments, a cold plate 110 is arranged in contact with an outer surface of the enclosure 106 to cool the PCB 101 housed in the enclosure 106. The cold plate 110 may be a metal plate used to cool the device 200 by directly transferring heat from the device 200 to a circulating liquid coolant (e.g., water or any other suitable coolant) flowing through channels within the cold plate 110, effectively removing excess heat from the PCB 101.

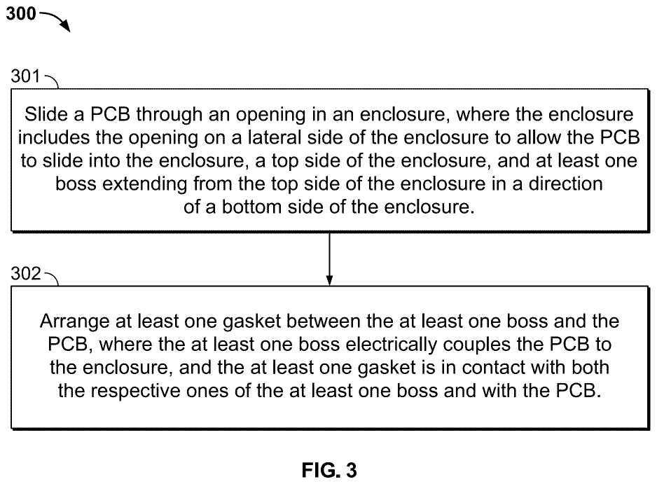

FIG. 3 shows an illustrative flowchart 300 of a method to house a PCB (e.g., PCB 101) in a rectangular-prism shaped enclosure (e.g., enclosure 106), in accordance with some embodiments of the present disclosure. The enclosure may include a top side of the enclosure, and at least one boss (e.g., bosses 108) extending from the top side of the enclosure in a direction of a bottom side of the enclosure. The enclosure may further include an opening on a lateral side of the enclosure.

At step 301, a PCB (e.g., PCB 101) is slid into an enclosure (e.g., enclosure 106) through an opening (e.g., a lateral opening, or any other opening that is orthogonal to top and bottom surfaces of the enclosure) of the enclosure. In some embodiments, prior to the sliding, electrically (e.g., providing ESD/EMI) conductive gaskets (e.g., gaskets 107) are stuck (e.g., using a conductive adhesive) to the PCB and thermally conductive TIMs (e.g., TIMs 105) are stuck (e.g., using a conductive adhesive) to the circuitry (e.g., top circuitry 102 and bottom circuity 103) on the PCB. While adhered, the gaskets and TIMs may be slid along with the PCB into the enclosure through the opening. The adhered gaskets and TIMs may include a slidable surface opposite to the sticky surface (i.e., the surface stuck to the PCB or the circuitry on the PCB) to help with the sliding. Those slidable surfaces may be exposed to slide along corresponding inner surfaces of the enclosure, during the sliding. The slidable surfaces may include slidable materials such as graphite, metal, mylar, polyamide, or any other suitable low friction material.

At step 302, one or more of the electrically conductive gaskets (e.g., gaskets 107) stuck to the PCB are arranged to contact one or more bosses (e.g., bosses 108) inside the enclosure. Because both the gaskets and bosses are electrically conductive, the PCB is electrically coupled to the enclosure via the contact. In some embodiments, electrically coupling the PCB and the enclosure may allow these components to be electrically coupled to a common ground. Thermally coupling the PCB and the enclosure may increase heat transfer from the PCB to the enclosure. Because the enclosure is monolithic and thermally conductive, the enclosure may maintain a roughly uniform temperature (e.g., to reduce, or even eliminate, thermal asymmetry) despite asymmetrical heat generation (e.g., by respective portions of the PCB or by respective circuitries mounted on the PCB) inside the enclosure. The thermally conductive TIMs may further be contact the inner surface of the enclosure, allowing more heat to be dissipated from the PCB circuitry directly to the enclosure.

In this disclosure (e.g., in connection with the devices of FIGS. 1-2), there may be multiple iterations of a single, or similar, element (e.g., multiple iterations of top circuitry 102, of bottom circuitry 103, of TIM 105, of gasket 107, and of boss 108). It will be understood that, as used herein, a singular reference to an element (e.g., to top circuitry 102, to bottom circuitry 103, to TIM 105, to gasket 107, or to boss 108) may refer to any one or more of those multiple iterations.

As used herein, “top” and “bottom” descriptors may characterize sides of an enclosure with respect to an intended orientation when housing a PCB. In view of how a PCB has two sides (e.g., on which electronic devices including circuitry may be disposed) with greater surface area than the other four sides of the PCB, it will be understood that top and bottom sides of an enclosure are the sides that are across from and substantially parallel to those two sides of the PCB with the greater surface area. The top side and the bottom side of the enclosure may be interchangeable with each other. The side (or open face) of the enclosure that contains the opening through which the PCB may be slid will be orthogonal to the top and bottom sides of the enclosure.

The term “monolithic” means one continuous material defining the entire structure.

The terms “an embodiment”, “embodiment”, “embodiments”, “the embodiment”, “the embodiments”, “one or more embodiments”, “some embodiments”, and “one embodiment” mean “one or more (but not all) embodiments” unless expressly specified otherwise.

The terms “including”, “comprising”, “having” and variations thereof mean “including but not limited to”, unless expressly specified otherwise.

The enumerated listing of items does not imply that any or all of the items are mutually exclusive, unless expressly specified otherwise.

The terms “a”, “an” and “the” mean “one or more”, unless expressly specified otherwise.

Devices that are in communication with each other need not be in continuous communication with each other, unless expressly specified otherwise. In addition, devices that are in communication with each other may communicate directly or indirectly through one or more intermediaries.

A description of an embodiment with several components in communication with each other does not imply that all such components are required. On the contrary a variety of optional components are described to illustrate the wide variety of possible embodiments. Further, although process steps, method steps, algorithms or the like may be described in a sequential order, such processes, methods, and algorithms may be configured to work in alternate orders. In other words, any sequence or order of steps that may be described does not necessarily indicate a requirement that the steps be performed in that order. The steps of processes described herein may be performed in any order practical. Further, some steps may be performed simultaneously.

When a single device or article is described herein, it will be readily apparent that more than one device/article (whether or not they cooperate) may be used in place of a single device/article. Similarly, where more than one device or article is described herein (whether or not they cooperate), it will be readily apparent that a single device/article may be used in place of the more than one device or article, or a different number of devices/articles may be used instead of the shown number of devices or programs. The functionality and/or the features of a device may be alternatively embodied by one or more other devices which are not explicitly described as having such functionality/features. Thus, other embodiments need not include the device itself.

At least certain operations that may have been illustrated in the figures show certain events occurring in a certain order. In alternative embodiments, certain operations may be performed in a different order, modified, or removed. Moreover, steps may be added to the above-described logic and still conform to the described embodiments. Further, operations described herein may occur sequentially or certain operations may be processed in parallel. Yet further, operations may be performed by a single processing unit or by distributed processing units.

The foregoing description of various embodiments has been presented for the purposes of illustration and description. It is not intended to be exhaustive or to be limited to the precise forms disclosed. Many modifications and variations are possible in light of the above teaching.

What is claimed is:

1. A device comprising:
a printed circuit board (PCB); and
a rectangular prism-shaped enclosure housing the PCB, the enclosure comprising:
an opening on a lateral side of the enclosure to allow the PCB to slide into the enclosure;
a top side of the enclosure,
at least one boss extending from the top side of the enclosure in a direction of a bottom side of the enclosure, and
at least one gasket arranged between the at least one boss and the PCB, wherein:
the at least one boss electrically couples the PCB to the enclosure, and
the at least one gasket is in contact with both the at least one boss and with the PCB.

2. The device of claim 1, wherein the top side and the PCB are thermally coupled using a thermal interface material (TIM) layer.

3. The device of claim 2, wherein the TIM layer comprises a slidable surface coupled to the top side and a sticky surface coupled to the PCB.

4. The device of claim 1, further comprising a first circuitry disposed on a first side of the PCB.

5. The device of claim 4, further comprising a second circuitry disposed on a second side of the PCB opposite the first side.

6. The device of claim 1, wherein each of the at least one gasket is electrically conductive.

7. The device of claim 1, wherein each of the at least one gasket comprises a slidable surface coupled to the at least one boss and a sticky surface coupled to the PCB.

8. The device of claim 7, wherein the slidable surface comprises a low friction material.

9. The device of claim 7, wherein the sticky surface comprises a conductive adhesive.

10. The device of claim 1, further comprising at least one cooling fin extending from an outer surface of the enclosure.

11. The device of claim 1, further comprising a cooling plate in contact with at least one outer surface of the enclosure.

12. A method of manufacturing a device comprising a printed circuit board (PCB) and a rectangular prism-shaped enclosure, the enclosure comprising an opening on a lateral side of the enclosure to allow the PCB to slide into the enclosure, a top side of the enclosure, and at least one boss extending from the top side of the enclosure in a direction of a bottom side of the enclosure, the method comprising:
sliding the PCB through the opening; and
arranging at least one gasket between the at least one boss and the PCB, wherein:
the at least one boss electrically couples the PCB to the enclosure, and
the at least one gasket is in contact with the respective ones of the at least one boss and with the PCB.

13. The method of claim 12, wherein the method further comprises thermally coupling the top side and the PCB using a thermal interface material (TIM) layer.

14. The method of claim 13, wherein the TIM layer comprises a slidable surface coupled to the enclosure and a sticky surface coupled to the PCB.

15. The method of claim 12, wherein the PCB comprises a first circuitry disposed on a first side of the PCB.

16. The method of claim 15, wherein the PCB further comprises a second circuitry disposed on a second side of the PCB opposite the first side.

17. The method of claim 12, wherein each of the at least one gasket is electrically conductive.

18. The method of claim 12, wherein each of the at least one gasket comprises a slidable surface coupled to the at least one boss and a sticky surface coupled to the PCB.

19. The method of claim 18, wherein the slidable surface comprises a low friction material.

20. A rectangular prism-shaped enclosure to house a printed circuit board (PCB), the enclosure comprising:
an opening on a lateral side of the enclosure to allow the PCB to slide into the enclosure;
a top side of the enclosure,
at least one boss extending from the top side of the enclosure in a direction of a bottom side of the enclosure, and
at least one gasket arranged between the at least one boss and the PCB, wherein:
the at least one boss electrically couples the PCB to the enclosure, and
the at least one gasket is in contact with both the at least one boss and with the PCB.
